(19) United States
(12) Patent Application Publication
(10) Pub. No.: US 2009/0238231 A1
(43) Pub. Date: Sep. 24, 2009

(54) LD MODULE

(76) Inventor: TAKASHI YAMANE, Tokyo (JP)

Correspondence Address: NEC CORPORATION OF AMERICA, 6535 N. STATE HWY 161, IRVING, TX, 75039, US

(21) Appl. No.: 12/403,065

(22) Filed: Mar. 12, 2009

(30) Foreign Application Priority Data
Mar. 19, 2008 (JP) 2008-071163

(51) Int. Cl. H01S 5/026

(52) U.S. Cl. 372/50.21

(57) ABSTRACT

The present invention is to provide an LD module that can detect a wavelength fluctuation with a simple configuration and can reduce its size and prices. The LD module includes a double-sided light-emitting LD element for emitting an output light and a backward light in both forward and backward directions, a reference LD element whose temperature dependence of an oscillation wavelength is different from that of the double-sided light-emitting LD element, and a PD for receiving a multiplexed wave of the backward light of the double-sided light-emitting LD element and an output light of the reference LD element and detecting a beat component generated by the multiplexing.

This application is based upon and claims the benefit of priority from Japanese patent application No. 2008-071163, filed on Mar. 19, 2008, the disclosure of which is incorporated herein in its entirety by reference.

### BACKGROUND ART

1. Technical Field

The present invention relates to an LD module.

2. Description of Related Art

FIG. 5 is a plan view of an LD module relating to the present invention.

In the LD (Laser Diode) module shown in the figure, a backward light 3 from an LD element 1 for modulation is split by a beam splitter 23 to two lights 25 and 26, one light 25 of which is received by a PD (Photo Diode) 21 as it is, while the other light 26 passes through a wavelength filter 24 and then, is received by a PD 22, and by comparing light-receiving currents 28 and 29 outputted from each of the PDs 21 and 22, a change in the wavelength is detected.

An example of such a technology is described in Patent Document 1 (Japanese Patent Laid Open Publication No. 2000-183823).

A “coherent optical transmitter” in Patent Document 1 includes a second light source for emitting light interfering with output light of a first light source close to the first light source so as to set both the light sources in the same environment in a transmission portion including the first light source, wherein light from both the light sources propagated through a transmission medium is received by a common photodetector in a receiving portion so as to create a beat signal. The coherent optical transmitter of the Patent Document 1 carries out heterodyne receiving or homodyne receiving and is operated as follows.

According to this coherent optical transmitter, since both a transmission light source and a local light source are arranged in the transmission portion, it becomes easy to keep ambient temperature of the both at the same and therefore, a difference in oscillation wavelengths between the transmission light source and the local light source can be kept constant by relatively simple control.

However, in the above related art, the following problems can occur:

(1) The number of components becomes larger than that of a usual LD module;

(2) The larger number of components makes size reduction difficult and in addition, a need to add a large number of expensive optical components such as a beam splitter 23 and a wavelength filter 24 unavoidably raises the price of the product as a whole; and

(3) Since the beam splitter 23 and the wavelength filter 24 are required to be arranged extremely precisely, drastic increase in time required for manufacture and occurrence of yield are unavoidable.

That is, in the case of a configuration example by the related art shown in the above-mentioned FIG. 5, in order to detect the wavelength change, it is necessary to constantly control power (APC: Automatic Power Control) of the backward light 3 of the LD element 1 for modulation with accuracy. Also, with the configuration of the related art shown in FIG. 5, since expensive optical components such as the beam splitter 23 and the wavelength filter 24 need to be used, there is a problem that a product price is raised. Moreover, with the configuration of the related art shown in FIG. 5, since extremely high accuracy is required for mounting positions or optical axis adjustment of the beam splitter 23, the wavelength filter 24, and light-receiving elements 21 and 22, expensive (highly accurate) manufacturing facilities with advanced manufacturing technology are needed, which is one of the factors to lower the yield.

### SUMMARY OF THE INVENTION

The present invention was made in view of the above circumstances and has an exemplary object to provide an LD module that can detect a wavelength fluctuation with a simple configuration and can reduce its size and prices.

In order to achieve the above exemplary object, the present invention is characterized as follows:

<LD Module>

The LD module according to an exemplary aspect of the present invention includes a double-sided light-emitting LD element for emitting an output light and a backward light in both forward and backward directions, a reference LD element whose temperature dependence of an oscillation wavelength is different from that of the double-sided light-emitting LD element, and a PD for receiving a multiplexed wave of the backward light of the double-sided light-emitting LD element and an output light of the reference LD element and detecting a beat component generated by the multiplexing.

### BRIEF DESCRIPTION OF THE DRAWINGS

The exemplary objects and features of the present invention will become more apparent from the consideration of the following detailed description taken in conjunction with the accompanying drawings, in which:

FIG. 1A is a top view illustrating an exemplary embodiment of an LD module according to the present invention, and FIG. 1B is a side view of FIG. 1A;

FIG. 2 is a diagram illustrating temperature dependence of oscillation wavelengths of an LD element 1 for modulation and a reference LD element 4 shown in FIGS. 1A and 1B;

FIG. 3 is a plan view illustrating another exemplary embodiment of the LD module according to the present invention;

FIG. 4 is a plan view illustrating another exemplary embodiment of the LD module according to the present invention; and

FIG. 5 is a plan view of the LD module relating to the present invention.

### DESCRIPTION OF THE EXEMPLARY EMBODIMENTS

### Exemplary Embodiments

The present invention provides a configuration that can detect an oscillation wavelength in a laser module used in an optical transmitter.

An exemplary embodiment of an LD module according to the present invention comprises a double-sided light-emitting LD element for emitting an output light and a backward light in both forward and backward directions, a reference LD element whose temperature dependence of an oscillation wavelength is different from that of the double-sided light-emitting LD element, and a PD for receiving a multiplexed wave of the backward light of the double-sided light-emitting LD element and an output light of the reference LD element and detecting a beat component generated by the multiplexing.

According to the above configuration, since an LD module that can detect wavelength fluctuation can be configured with a simple configuration of addition of only a reference LD element, size and price reduction is facilitated.

Another exemplary embodiment of the LD module according to the present invention is characterized in that, in addition to the above configuration, the double-sided light-emitting LD element and the reference LD element are formed in the lump on a single chip.

Another exemplary embodiment of the LD module according to the present invention is characterized in that, in addition to the above configuration, the double-sided light-emitting LD element is an LD element for modulation.

Another exemplary embodiment of the LD module according to the present invention is characterized in that, in addition to the above configuration, the double-sided light-emitting LD element is an integrated LD element of external modulator.

Another exemplary embodiment of the LD module according to the present invention is characterized in that, in addition to the above configuration, the double-sided light-emitting LD element is a CW-LD element.

### Exemplary Embodiment 1

An exemplary embodiment of an LD module according to the present invention will be described below.

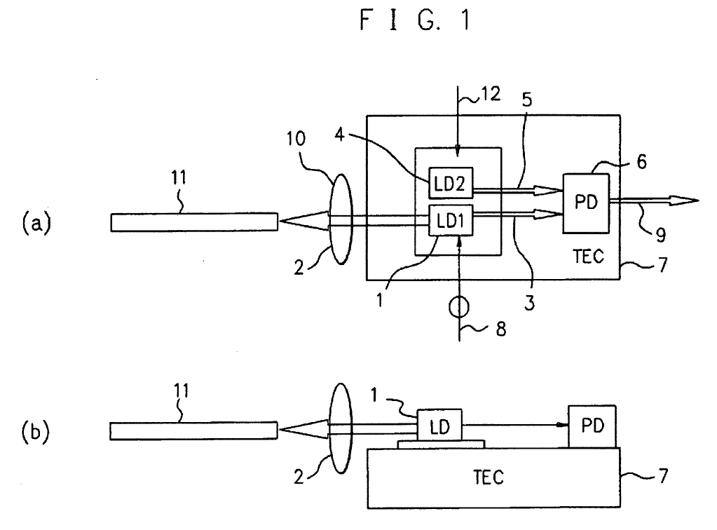

FIG. 1A is a top view illustrating an exemplary embodiment of the LD module according to the present invention and FIG. 1B is a side view of FIG. 1A.

On an electronic temperature control element (Peltier element, also called thermo electrical cooling module (TEC)) 7 whose surface temperature is changed by a current amount flowing therethrough, an LD element 1 for modulation as a double-sided light-emitting LD element converting a modulation (electric) signal 8 to an optical signal 2, a reference LD element 4 whose temperature dependence of an oscillation wavelength is different from that of the LD element 1 for modulation, and a PD element 6 for receiving a backward light 3 of the LD element 1 for modulation and an output light 5 of the reference LD element 4 and converting them to an electric current 9 are mounted.

The components mounted on the electronic temperature control element (Peltier element) 7 may be considered to be at the same temperature by a cooling/heating effect of the Peltier element. In a wavelength multiplexing communication (WDM) or the like often used by those skilled in the art, a desired oscillation wavelength is obtained by adjusting the temperature of the electronic temperature control element 7.

The forward light 2 of the LD element 1 for modulation is converged by a lens 10 and inputted into an optical fiber 11.

The reference LD element 4 emits light when a direct current 12 with ACC (Automatic Current Control) is supplied.

The configuration of the exemplary embodiment has been described in detail, but since a detailed structure and a manufacturing method of the LD module are well known to those skilled in the art and are not directly related to the present invention, the detailed configuration thereof will be omitted.

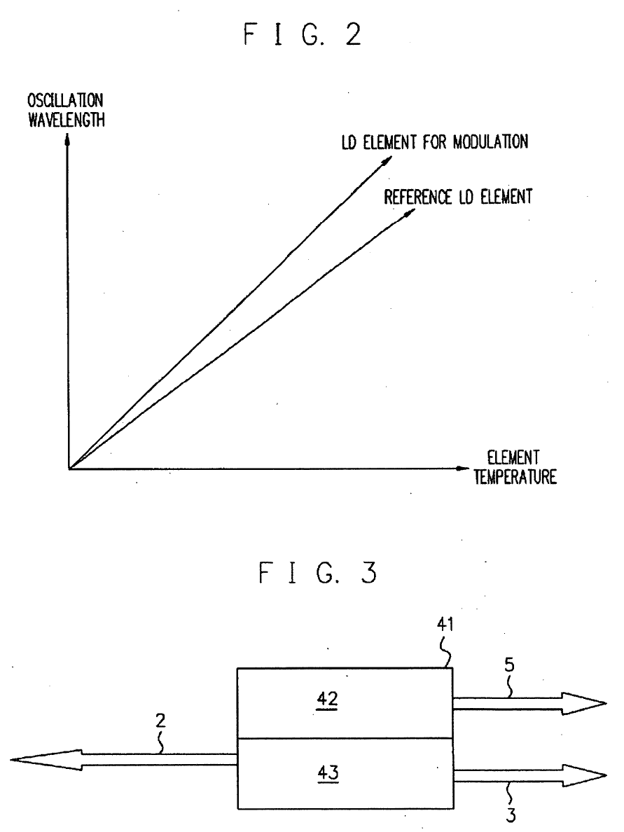

An operation of the exemplary embodiment shown in FIGS. 1A and 1B will be described referring to FIG. 2.

FIG. 2 is a diagram illustrating the temperature dependence of the oscillation wavelengths of the LD element 1 for modulation and the reference LD element 4 shown in FIGS. 1A and 1B. In FIG. 2, the horizontal axis indicates an element temperature, while the vertical axis indicates the oscillation wavelength.

FIG. 2 shows that the LD element in FIG. 1 in general has a characteristic that the oscillation wavelength is changed according to the temperature.

For the LD module according to the present invention, two elements (the LD element 1 for modulation and the reference LD element 4) whose (oscillation wavelength) temperature dependences are different are used. In this exemplary embodiment, it is shown that the LD element 1 for modulation has a larger wavelength fluctuation amount per unit temperature change.

As is known from FIG. 2, the higher the element temperature becomes, the larger a difference in the oscillation wavelength (≈beat frequency) between the two LD elements (the LD element 1 for modulation and the reference LD element 4 in FIG. 1) becomes.

Since an optical wave is expressed by the following expression (1):

c=fλ (C: light speed 2.99792458×108 m/second, f: frequency, λ: wavelength) (1)

it can be said that the frequency f corresponds to the wavelength λ on a one-on-one basis (f∝1/λ).

Since the optical wave is a wave, if the backward light 3 of the LD element 1 for modulation in FIG. 1 is expressed by the following expression (2):

S1=K1·sin(f1) (2)

where K1 is an arbitrary constant; and

the output light 5 of the reference LD element 4 is expressed by the following expression (3):

S2=K2·sin(f2) (3)

where K2 is an arbitrary constant,

the multiplexed light is expressed by the following expression (4):

S1+S2=K3·sin [(f1+f2)/2]·sin [(f1−f2)/2] (4)

where K3 is an arbitrary constant and includes a component (f1−f2)/2 half the frequency difference of the both waves. Since (f1+f2)/2 becomes an extremely large frequency (>100 THz) that cannot be detected by an electric circuit, it can be negligible.

Thus, by converting the optical wave in which the backward light 3 of the LD element 1 for modulation and the output light 5 of the reference LD element 4 are multiplexed to a light-receiving current 9 by the light-receiving element (PD) 6 and by detecting a frequency thereof by a frequency detection circuit, a change in the wavelength can be obtained.

That is, in FIG. 1, the LD element 1 for modulation outputs the forward light 2 and the backward light 3. Moreover, the reference LD element 4 whose temperature dependence of the oscillation wavelength is different from that of the LD element 1 for modulation outputs the non-modulated light 5 only in the same direction as that of the backward light 3 of the LD element 1 for modulation. Thereby, in a multiplexed wave of the backward light 3 of the LD element 1 for modulation and the output light 5 of the reference LD element 4, a beat component, which is a frequency difference (∝wavelength difference) of the two waves is generated.

Thus, by examining the frequency of the beat component, a fluctuation in the wavelength can be detected.

### Exemplary Embodiment 2

FIG. 3 is a plan view illustrating another exemplary embodiment of the LD module according to the present invention.

As shown in FIG. 3, with regard to the LD for modulation and the LD for reference, the LD element 1 for modulation and the LD element 4 for reference can be formed in the lump on a single chip in an LD element manufacturing process (this method can be considered the most ideal). FIG. 3 shows that an LD portion 43 for modulation and a reference LD portion 42 are formed on a single chip 41.

### Exemplary Embodiment 3

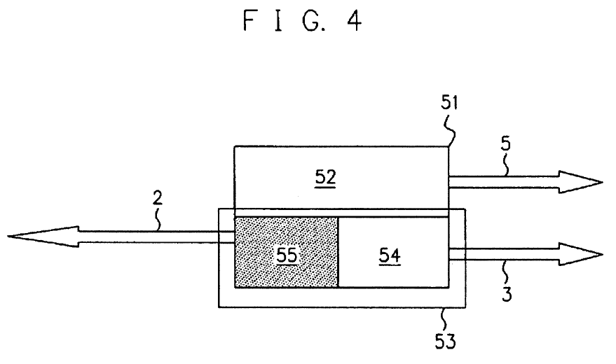

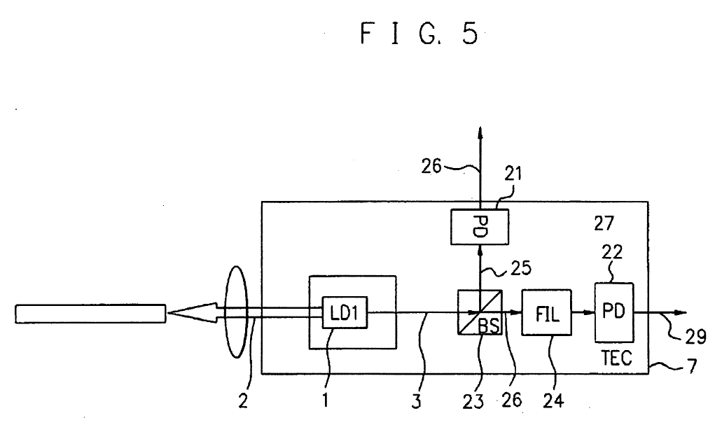

FIG. 4 is a plan view illustrating another exemplary embodiment of the LD module according to the present invention.

As shown in FIG. 4, even if the LD element for modulation is changed to an integrated LD element of external modulator, configuration is possible without a problem. FIG. 4 shows that a reference LD portion 52 and an integrated LD 53 of external modulator (modulator portion 55, CW-LD portion 54) are formed on a single chip 51.

### Exemplary Embodiment 4

Instead of the LD element for modulation, a CW-LD element not carrying out modulation can be used in the configuration without a problem.

In the above, if the backward light 3 of the LD element 1 for modulation and the output light 5 of the LD element 4 for reference whose temperature dependence of the oscillation wavelength is different from that of the LD element 1 for modulation are multiplexed, the frequency of the beat component generated by that follows a change in the oscillation wavelength of the LD element 1 for modulation, and it becomes possible to detect the wavelength fluctuation by detecting the frequency of the beat component.

As mentioned above, it is configured so that the wavelength detection is made possible only by adding the LD element 4 for reference. This exemplary embodiment has an advantage that since the beat frequency generated by the multiplexing does not depend on power of the LD element 1 for modulation, it is not necessary to accurately control output power of the backward light 3 of the LD element 1 for modulation.

<Description of the Advantages>

As mentioned above, in the present invention, advantages described below are exerted.

A first advantage is that since an LD module that can detect the wavelength fluctuation can be configured only by adding only a reference LD element, size reduction is easy.

A second advantage is that since the reference LD element does not require high mounting accuracy, drop in yield/reliability is not incurred.

A third advantage is that since the number of added components is small, it is effective in price reduction.

<Difference from the Related Art>

The invention described in Patent Document 1 does not create a beat signal for wavelength detection but uses the beat signal itself as a transmission signal. That is, in the invention described in Patent Document 1, the frequency of the beat signal is changed according to a signal to be transmitted, and the signal is demodulated on the receiving side on the basis of the beat frequency (corresponding to FM modulation in electric communication).

On the other hand, in the invention of the present application, transmission of a signal is not an exemplary object but the beat signal is used with the purpose of detection of an oscillation wavelength for highly-accurate wavelength control in the WDM (Wavelength Division Multiplex). Thus, not an optical signal transmitting through an optical fiber but a backward light of the LD outputted separately from the transmission optical signal is used.

In the above, according to the present invention, the LD module that can detect wavelength fluctuation can be configured with the simple configuration of adding only a reference LD element, and size and price reduction is facilitated.

The LD module according to the present invention can be used in an optical transmitter or an optical transmitter/receiver.

While the invention has been particularly shown and described with reference to exemplary embodiments thereof, the invention is not limited to these exemplary embodiments. It will be understood by those of ordinary skill in the art that various changes in form and details may be made therein without departing from the spirit and scope of the present invention as defined by the claims.

What is claimed is:

1. An LD module comprising:
a double-sided light-emitting LD element for emitting an output light and a backward light in both forward and backward directions;
a reference LD element whose temperature dependence of an oscillation wavelength is different from that of the double-sided light-emitting LD element; and
a PD for receiving a multiplexed wave of the backward light of the double-sided light-emitting LD element and an output light of the reference LD element and detecting a beat component generated by the multiplexing.

2. The LD module according to claim 1, wherein the double-sided light-emitting LD element and the reference LD element are formed in the lump on a single chip.

3. The LD module according to claim 1, wherein the double-sided light-emitting LD element is an LD element for modulation.

4. The LD module according to claim 1, wherein the double-sided light-emitting LD element is an integrated LD element of external modulator.

5. The LD module according to claim 1, wherein the double-sided light-emitting LD element is a CW-LD element.
